(19) United States
(12) Patent Application Publication
(10) Pub. No.: US 2022/0124905 A1
(43) Pub. Date: Apr. 21, 2022

(54) IR WINDOW PACKAGE IN HEADSET

(71) Applicant: BUJEON CO., LTD., Ansan-si (KR)

(72) Inventors: Donghyun SEO, Ansan-si (KR); ki-bum BANG, Hwaseong-si (KR); Sunwoo PARK, Ansan-si (KR)

(21) Appl. No.: 17/399,131

(22) Filed: Aug. 11, 2021

(30) Foreign Application Priority Data
Oct. 20, 2020 (KR) 10-2020-0136359

(51) Int. Cl. H05K 1/02; H05K 1/18; H04R 1/10

(52) U.S. Cl. CPC H05K 1/0274; H05K 1/185; H05K 1/189; H04R 1/1041; H04R 2420/07; H04R 1/1016; H05K 2201/10151; H05K 2201/10083; H04R 1/1075

(57) ABSTRACT

The present invention provides an IR window assembly in which an IR window, an IR sensor, and a portion of a PCB, on which the IR sensor is mounted, are structurally integrated. The IR window assembly is mounted on the FPCB, and mounted in a position where infrared detection is easy in audio devices such as headsets.

### CROSS-REFERENCE TO RELATED APPLICATION(S)

This application claims the benefit of Korean Patent Application No. 10-2020-0136359 filed on Oct. 20, 2020 with the Korean Intellectual Property Office, the disclosure of which is incorporated herein by reference in its entirety.

### TECHNICAL FIELD

The present invention relates to an IR, i.e., an infrared window structure of a headset. More particularly, the present invention relates to an IR window package or assembly of a headset that is excellent in waterproof property and durability and assures easy manufacture.

### BACKGROUND ART

In a headset, for example, a wireless headset equipped with a micro speaker, there is a method of listening to audio, playing a game, or watching a movie by using infrared rays, that is, an IR signal instead of a Bluetooth method. This method is performed by locating an IR docking station with an IR transmitter (e.g., vehicle audio) and a headset within the IR radio wave area. The left and right stereo channels are converted into two discrete carrier frequencies, compressed, multiplexed, and transmitted to the outside as IR light waves. At this time, the IR detection means (IR sensor) inside the headset captures an IR light wave, goes through the reverse process to the previous one, and is converted into an audible electrical signal and transmitted to an ear.

Sound equipment such as IR headset has no obstacles in its path so that it can directly receive IR transmitted from an audio, and therefore, is limited in the distance restriction, but it has the advantages in that high-quality sound reproduction is superior to that of Bluetooth, and two persons can listen to different sounds at the same time without interference using two channels, and it can be widely applied to watching TV or watching movies.

In regard to the IR sound equipment, Korean Registered Utility Model No. 20-0488526 discloses a microphone and speaker wireless transmission/reception system which comprises a hall microphone that receives the input of external audio to the neckband type microphone body, and an insert microphone that receives the input of other external audio. Korean Patent No. 10-1091714 discloses an infrared-based wireless portable voice receiving device which comprises an infrared sensor that is mounted on the outside of the front side of a speaker housing and receives infrared signals, and a control unit that receives the input of the received signal, demodulates it, and outputs it to a speaker.

In relation to the IR sound instrument, the waterproofness issues must be resolved in the manufacture and assembly of an assembly including an IR sensor that detects an IR signal. However, the conventional techniques arts have the disadvantages in that the microphone mounting structure to prevent interference with speaker parts is excessively complicated, and thus, the IR sensor is mounted on the outside of the sound instrument, and the waterproofness and durability are not considered. Even when the IR sensor unit is mounted on the board inside the housing, it is manufactured separately from the substrate and attached with tape, and an empty space exists between the substrate and the surrounding members, whereby it is not possible to solve the disadvantages of easy intrusion of foreign matters and weak waterproofness.

Considering the above circumstances, the present inventors have developed an IR window assembly having a new structure that secures sound quality performance and improves waterproofness and durability in headsets, particularly TWS products.

### DETAILED DESCRIPTION OF THE INVENTION

### Technical Problem

Therefore, it is an object of the present invention to provide an IR window assembly that is highly waterproof, prevents external foreign matters, and is robust and has excellent physical properties.

It is another object of the present invention to provide an audio device provided with the IR window assembly that can reproduce high-quality sound, save space, and efficiently use space.

### Technical Solution

In order to achieve the above object, an embodiment of the present invention provides an IR window assembly comprising: an IR sensor mounted on PCB and PCB, and an IR window that tightly surrounds the IR sensor and closes it therein, wherein the IR window is subjected to a composite injection molding like a PCB equipped with an IR sensor, so that the IR window, the IR sensor and the part of the PCB where the IR sensor is mounted are structurally integrated.

The IR window may be made of a thermosetting resin.

Another embodiment of the present invention provides a headset comprising: the IR window assembly; an FPCB which consists of a main part extending in a height direction, and a mounting part extending from one part of the main part to a side surface so that a substrate surface faces outward, in which the IR window assembly is mounted so that it faces outward to the mounting part; and a speaker driver.

The mounting part of the FPCB extends to the side from the part where the main part faces the speaker driver, and the IR window assembly may be mounted so as to face the housing constituting the exterior of the headset near the free end, which is the end of the mounting part.

### Advantageous Effects

According to the present invention, the inflow of foreign matters is impossible due to the integrated coupling between parts, and a waterproof function can be realized by changing the shape of the IR window using the flexibility of silicone material. In addition, since no adhesive member is used, the process is simplified and space can be saved.

### BRIEF DESCRIPTION OF THE DRAWINGS

FIG. 1 is a cross-sectional view taken along a longitudinal center of an IR window assembly of the present invention;

FIGS. 2A to 2C are diagrams for showing an example of a manufacturing and mounting process of the window assembly of the present invention;

FIG. 3 is a perspective view of a headset of the present invention having an FPCB equipped with an IR window assembly of the present invention; and

FIG. 4 is a perspective view of a headset of the present invention having an FPCB equipped with an IR window assembly of the present invention as viewed from the rear.

### DETAILED DESCRIPTION OF THE EMBODIMENTS

Objects and effects of the present invention, and technical configurations for achieving them will become clear with reference to the embodiments described in detail below in conjunction with the accompanying drawings. In describing the present invention, if it is determined that a detailed description of a well-known function or configuration may unnecessarily obscure the gist of the present invention, the detailed description thereof will be omitted.

Throughout the specification, when an element “includes” a certain component, it means that the element may further include other components, without excluding other components, unless otherwise stated. On the other hand, in the embodiment of the present invention, each of the components, functional blocks or means may be composed of one or more sub-components.

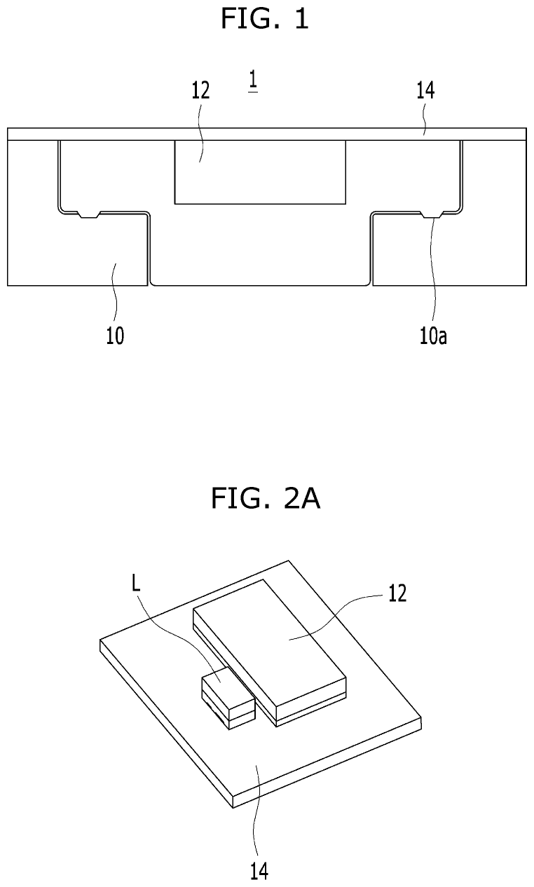

FIG. 1 is a cross-sectional view taken along a longitudinal center of an IR window assembly of the present invention. “Assembly 1” is used with the same meaning as a package. An IR sensor 12 is mounted on a PCB 14, and an IR window 10 is tightly formed around the IR sensor 12 to close the IR sensor 12 therein. The IR window 10 is subjected to a composite injection molding like the PCB 14 on which the IR sensor 12 is mounted, as will be described later. Thus, the IR window 10, the IR sensor 12 and the portion of the PCB 14 associated therewith are structurally integrated. In the conventional technique, since the IR window 10 is attached to the PCB 14 using an adhesive member such as a tape, instead of using injection molding, the inflow of foreign matters is possible and the waterproofness is weak, which adversely affects electronic products including the IR sensor 12.

In the present invention, the material of the IR window 10 is not particularly limited as long as it is a material that can pass infrared rays, for example, such as a thermosetting resin, but it is preferable to use silicone with good elasticity and strong durability against scratches. The shape of the IR window 10 can be freely designed, such as a square shape, a circular shape, or an elliptical shape.

When other members are mounted around the IR window 10, an embossing 10a for waterproofing and foreign matter prevention may be further formed on the bonding surface portion as shown in the figure.

According to the IR window assembly 1 of the present invention, the inflow of foreign matters is impossible due to the integrated coupling between parts, a waterproof function can be achieved by changing the shape of the IR window 10 using the flexibility of silicone material, and since no adhesive member is used, the process is simplified and space can be saved.

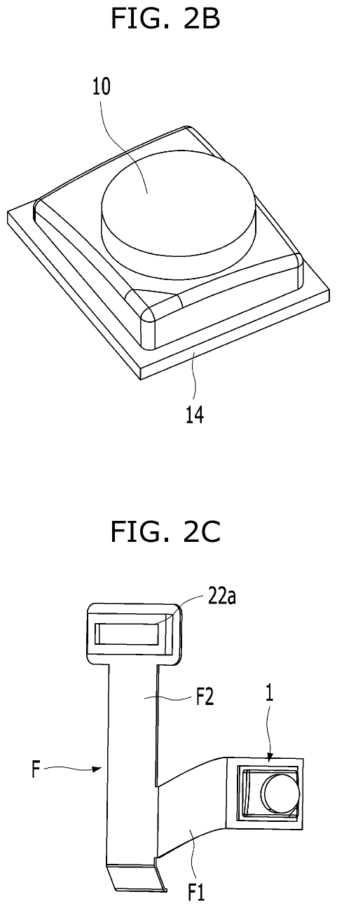

Next, one example of the manufacturing and mounting process of the window assembly 1 of this invention is described with reference to FIGS. 2A to 2C.

In FIG. 2A, an IR sensor 12 and an electronic device L such as an LED lamp are mounted on the PCB 14.

Here, as described above and as shown in FIG. 2, the IR window 10 is formed through a complex injection molding process to complete the IR window assembly 1.

The IR window assembly 1 of the present invention can be universally applied to electronic devices using IR. FIG. 2C is an example thereof, showing the mounting of the IR window assembly 1 on one side of the FPCB (F; flexible print circuit board) in which the middle part is bent. The FPCB F is composed of a main part F2 extending in the height direction, and a mounting part F1 extending from one part of the main part F2 to the side surface so that the substrate surface faces outward, and the IR window assembly 1 is mounted at the end of the mounting part F1 so that it faces outward. The main board 22a is integrally formed on the upper part of the main part F2.

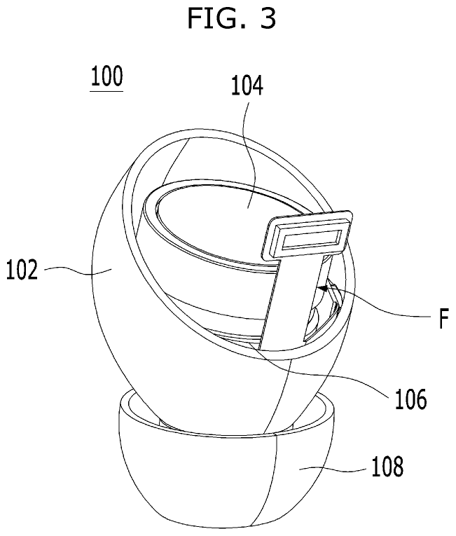

FIG. 3 is a perspective view of the headset 100 of the present invention having an FPCB F mounted with the IR window assembly 1 of the present invention.

An example of such a headset is well disclosed in the applicant's earlier application No. 10-2020-0085242, filed July 10, entitled “Microphone Mounting Structure of Headset”. A sleeve 108 that functions as an air tip is inserted into a soft housing 102, and a battery 104 and a speaker driver 106 are mounted sequentially from above in the inside of the housing 102. The upper portion of the main portion F2 of the FPCB F is exposed to the outside from the rear portion of the housing 102.

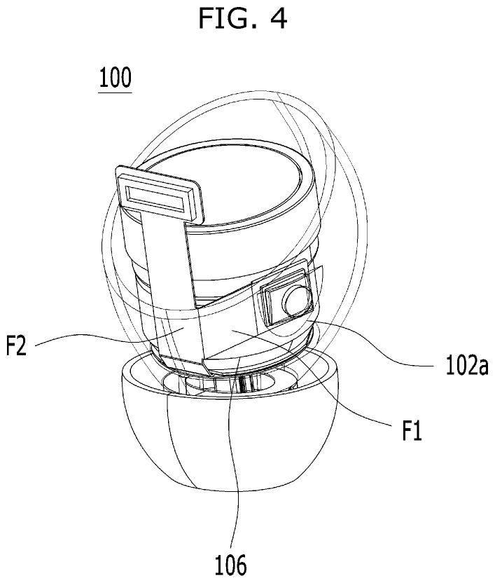

FIG. 4 is a perspective view of a headset 100 of the present invention having an FPCB F equipped with an IR window assembly 1 of the present invention as viewed from the rear.

The mounting portion F1 of the FPCB F extends to the side surface from a portion where the main portion F2 faces the speaker driver 106. And, the IR window assembly 1 is mounted near a free end, which is the end of the mounting part F1. When viewed from the side, most heights extend over the speaker driver 106. Since the speaker driver 106 provides a relatively large space between the housing 102 and the relatively small diameter portion compared to the battery 104, the arrangement makes efficient use of space. In addition, since the portion of the FPCB F on which the IR window assembly 1 is mounted is adjacent to the speaker driver 106, it is reasonable in terms of converting an infrared signal into an electric signal.

In addition, since the IR window assembly 1 is naturally located near the middle height of the headset 100, it is easy to detect and capture IR emitted from an IR transmitter (not shown).

Reference numeral 102a denotes an external window on the housing 102 that is opened so that the IR window assembly 1 can detect IR. The outer window 102a may be an empty space, but any sheet or panel may be used as long as it is a material that can pass infrared light easily.

Although an example of applying the IR window assembly 1 of the present invention to the headset 100 of a specific embodiment has been described above, it should be noted that the structure of IR window assembly 1 in FIG. 1 can be universally applied to electronic devices using IR.

The description related to the above-described embodiments is merely an exemplary explanation of the technical idea of the present invention, and those of ordinary skill in the art will understand that various modifications and variations can be made to the embodiments of the invention without departing from the essential characteristics of the present invention.

What is claimed is:

1. An IR window assembly comprising:
an IR sensor mounted on PCB and PCB, and
an IR window that tightly surrounds the IR sensor and closes it therein,
wherein the IR window is subjected to a composite injection molding like a PCB equipped with an IR sensor, so that the IR window, the IR sensor and the part of the PCB where the IR sensor is mounted are structurally integrated.

2. The IR window assembly of claim 1, wherein:
the IR window is made of a thermosetting resin.

3. A headset comprising:
the IR window assembly of claim 1;
an FPCB which consists of a main part extending in a height direction, and a mounting part extending from one part of the main part to a side surface so that a substrate surface faces outward, in which the IR window assembly is mounted so that it faces outward to the mounting part; and
a speaker driver.

4. A headset comprising:
the IR window assembly of claim 2;
an FPCB which consists of a main part extending in a height direction, and a mounting part extending from one part of the main part to a side surface so that a substrate surface faces outward, in which the IR window assembly is mounted so that it faces outward to the mounting part; and
a speaker driver.

5. The headset of claim 3, wherein:
the mounting part of the FPCB extends to the side from the part where the main part faces the speaker driver, and the IR window assembly is mounted so as to face the housing constituting the exterior of the headset near a free end, which is the end of the mounting part.

6. The headset of claim 4 wherein:
the mounting part of the FPCB extends to the side from the part where the main part faces the speaker driver, and the IR window assembly is mounted so as to face the housing constituting the exterior of the headset near a free end, which is the end of the mounting part.
